(19) United States
(12) Patent Application Publication
(10) Pub. No.: US 2025/0264794 A1
(43) Pub. Date: Aug. 21, 2025

(54) OPTICAL PROXIMITY CORRECTION METHOD, MASK MANUFACTURING METHOD AND SEMICONDUCTOR CHIP MANUFACTURING METHOD USING THE SAME

(71) Applicant: Samsung Electronics Co., Ltd., Suwon-si (KR)

(72) Inventors: Mijin KWON, Suwon-si (KR); Hungbae AHN, Suwon-si (KR); Seunghune YANG, Suwon-si (KR)

(73) Assignee: Samsung Electronics Co., Ltd., Suwon-si (KR)

(21) Appl. No.: 18/768,632

(22) Filed: Jul. 10, 2024

(30) Foreign Application Priority Data
Feb. 16, 2024 (KR) 10-2024-0022518

(51) Int. Cl. G03F 1/36; G03F 1/70; G03F 7/00

(52) U.S. Cl. CPC G03F 1/36; G03F 1/70; G03F 7/70441

(57) ABSTRACT

An optical proximity correction (OPC) method for manufacturing a semiconductor chip includes: detecting corners of an original target pattern having a polygonal shape; rounding off the corners to generate a curved target pattern; dividing the curved target pattern into a linear section pattern and a curved section pattern; applying Manhattan OPC to the linear section pattern to generate a modified linear section pattern; applying curvilinear OPC to the curved section pattern to generate a modified curved section pattern; and merging the modified linear section pattern and the modified curved section pattern to generate a corrected pattern.

### CROSS-REFERENCE TO RELATED APPLICATION(S)

This application claims benefit of priority under 35 U.S.C. § 119 to Korean Patent Application No. 10-2024-0022518 filed on Feb. 16, 2024 in the Korean Intellectual Property Office, the disclosure of which is incorporated herein by reference in its entirety.

### BACKGROUND

Various example embodiments relate to an optical proximity correction (OPC) method, a mask manufacturing method using the same and/or a semiconductor chip manufacturing method.

In general, patterns of semiconductor chips are formed by a photolithography process and an etching process. A layout for a pattern of a semiconductor chip to be formed on a substrate is designed. When a circuit pattern on a mask is transferred onto a substrate through the photolithography process to form the circuit pattern (hereinafter, referred to as a “a transferred circuit pattern”) on the substrate, there is a difference between the transferred circuit pattern on the substrate and an actually designed circuit pattern. Such a difference may be due to an optical proximity effect in the photolithography process and/or to a loading effect in the etching process.

As a method for accurately transferring a circuit pattern on a mask onto a substrate, process proximity correction (PPC) technology for correcting or adjusting a transferred circuit pattern in consideration of deformation of the transferred circuit pattern on the substrate may be used. The PPC technology predicts and analyzes the optical proximity effect and the loading effect in advance and corrects the layout of the circuit pattern on the mask according to an analysis result, and an OPC method is mainly used in the photolithography process.

The OPC method is divided into a model-based OPC method and a rule-based OPC method. The model-based OPC method is a method of correcting a circuit pattern of a mask by applying one model to all chips (full-chip) on a substrate, while the rule-based OPC method is a method of correcting a circuit pattern of a mask by applying one rule to all chips on a substrate.

### SUMMARY

Various example embodiments provide an optical proximity correction method, a mask manufacturing method and/or a semiconductor chip manufacturing method that can reduce a capacity of data including a layout pattern, while allowing the layout pattern on the mask to more easily satisfy a mask or design rule.

According to various example embodiments, an optical proximity correction (OPC) method for manufacturing a semiconductor chip includes: detecting corners of an original target pattern having a polygonal shape; rounding off the corners to generate a curved target pattern; dividing the curved target pattern into a linear section pattern and a curved section pattern; applying Manhattan OPC to the linear section pattern to generate a modified linear section pattern; applying curvilinear OPC to the curved section pattern to generate a modified curved section pattern; and merging the modified linear section pattern and the modified curved section pattern to generate a corrected pattern.

Alternatively or additionally according to various example embodiments, a semiconductor chip manufacturing method includes designing a layout for a semiconductor chip; performing optical proximity correction (OPC) on the layout; manufacturing a mask corresponding to the layout after performing OPC; and manufacturing the semiconductor chip using the mask, wherein the mask comprises a layout pattern, and the layout pattern comprises a polygonal section and a curved section.

Alternatively or additionally according to various example embodiments, a mask manufacturing method for a semiconductor chip includes: performing optical proximity correction (OPC) on a layout; receiving mask tape-out (MTO) design data after performing OPC; performing mask data preparation after receiving the MTO design data; performing a photolithography process on a substrate of a mask, based on the mask data using an electronic beam after performing the mask data preparation; and forming the mask by performing at least one of a developing, etching or cleaning process on the substrate after the photolithography process. The performing OPC comprises: detecting corners of an original target pattern having a polygonal shape; rounding off the corners to generate a curved target pattern; dividing the curved target pattern into a linear section pattern and a curved section pattern; applying Manhattan OPC to the linear section pattern to generate a modified linear section pattern; applying curvilinear OPC to the curved section pattern to generate a modified curved section pattern; and merging the modified linear section pattern and the modified curved section pattern to generate a corrected pattern.

### BRIEF DESCRIPTION OF DRAWINGS

The above and other aspects, features, and advantages of various example embodiments will be more clearly understood from the following detailed description, taken in conjunction with the accompanying drawings, in which:

FIG. 1 is a block diagram illustrating a computing system performing optical proximity correction (OPC) according to various example embodiments;

FIG. 2 is a flowchart illustrating a method of manufacturing a semiconductor chip according to various example embodiments;

FIG. 3 is a flowchart illustrating an OPC method according to various example embodiments;

FIGS. 4 and 5 are diagrams illustrating a method of dividing sections of a target pattern according to various example embodiments;

FIG. 6 is a diagram illustrating a method of detecting a linear section in a curved target pattern according to various example embodiments;

FIGS. 7 and 8 are diagrams illustrating a method of performing Manhattan OPC on a first section pattern according to various example embodiments;

FIGS. 9 and 10 are diagrams illustrating a method of performing the curvilinear OPC on a second section pattern according to various example embodiments;

FIGS. 11 and 12 are diagrams illustrating a method of merging a modified first section pattern and a modified second section pattern according to various example embodiments;

FIGS. 13A to 13C are diagrams comparing and illustrating Manhattan OPC, curvilinear OPC, and OPC according to various example embodiments; and

FIG. 14 is a flow chart illustrating a mask manufacturing method according to various example embodiments.

### DETAILED DESCRIPTION

Hereinafter, some example embodiments will be described with reference to the accompanying drawings.

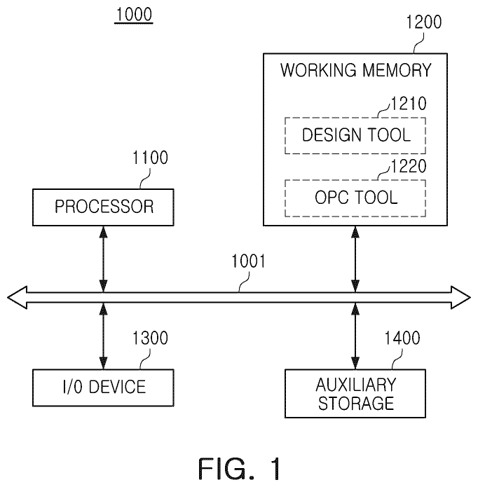

FIG. 1 is a block diagram illustrating a computing system 1000 performing optical proximity correction (OPC) according to various example embodiments.

Referring to FIG. 1, the computing system 1000 may include at least one processor 1100 connected to a system bus 1001, a working memory 1200, an input/output (I/O) device 1300 and an auxiliary storage 1400.

The computing system 1000 may be provided as a dedicated device for generating/correcting an OPC model or as a dedicated device for performing semiconductor design including the same. For example, the computing system 1000 may include various design and verification simulation programs. The processor 1100, the working memory 1200, the I/O device 1300 and the auxiliary storage 1400 may be electrically connected through the system bus 1001 and exchange data and/or instructions with each other. The bus 1001 may be or include a wired bus and/or a wireless bus; example embodiments are not limited thereto. Meanwhile, a configuration of the system bus 1001 is not limited to the above description, and may further include other approaches for efficient management.

The processor 1100 may be implemented to execute at least one instruction. For example, the processor 1100 may be implemented to execute software (one or more of application programs, operating systems, device drivers) to be executed in the computing system 1000. The processor 1100 may execute an operating system that is loaded into the working memory 1200. The processor 1100 may execute various application programs to be driven based in the operating system. For example, the processor 1100 may be or include (or be included in) a central processing unit (CPU), a microprocessor, an application processor (AP) or any processing device similar thereto.

The working memory 1200 may be implemented to store at least one instruction. For example, the working memory 1200 may be loaded with an operating system or application programs. When the computing system 1000 is booted, an OS image stored in the auxiliary storage 1400 may be loaded into the working memory 1200 based on a booting sequence. General I/O operations of the computing system 1000 may be supported by the operating system. Additionally or alternatively, application programs may be loaded into the working memory 1200 to be selected by a user and/or to provide a basic service. In particular, as described above, a design tool 1210 for semiconductor design and/or an OPC tool 1220 for OPC may be loaded from the auxiliary storage 1400 into the working memory 1200.

In some examples, the working memory 1200 may be or may include a volatile memory such as a dynamic random access memory (DRAM) and/a static random access memory (SRAM), etc., and/or a non-volatile memory such as at least one of flash memory, a phase change random access memory (PRAM), a resistance random access memory (RRAM), a nano floating gate memory (NFGM), a polymer random access memory (PoRAM), a magnetic random access memory (MRAM), a ferroelectric random access memory (FRAM), etc.

The design tool 1210 may perform a function of changing or characterizing shapes and/or positions of specific layout patterns to be different from those defined by a design rule. In some example embodiments, the design tool 1210 may perform a design rule check (DRC) in a changed bias data condition.

The OPC tool 1220 may perform an OPC function on a layout pattern. OPC may indicate that a pattern to be formed on the mask is adjusted or corrected such that the pattern actually formed on the substrate become more similar to a target pattern, by reflecting a difference between a pattern formed on a mask and a pattern actually formed on a substrate that may be caused by an optical proximity effect when performing a photolithography process on a substrate using the mask. For example, OPC may include expanding an overall size of the patterns that make up the layout and/or modifying the corner portions and/or adding or removing serifs and/or adding sub-resolution assist features (SRAF) such as inriggers and/or outriggers.

The I/O device 1300 may control user inputs and outputs from user interface devices. For example, the I/O device 1300 may include input units such as one or more of a keyboard, a keypad, a mouse, and a touchscreen to receive information from a designer. Using the I/O device 1300, the designer may receive information on a semiconductor region and/or data paths that require or expect adjusted operating characteristics. Alternatively or additionally, the I/O device 1300 may include an output unit such as a printer and/or a display to display a processing process and results of the design tool 1210 or the OPC tool 1220.

The auxiliary storage 1400 may be provided as a storage medium of the computing system 1000. The auxiliary storage 1400 may store one or more of application programs, an OS image, and various data. The auxiliary storage 1400 may be provided in the form of a mass storage device such as one or more of a memory card (one or more of MMC, eMMC, SD, Micro SD, etc.), hard disk drive (HDD), solid state drive (SSD), universal flash storage (UFS), etc.

For example, the auxiliary storage 1400 may include a database (DB) for storing designed layout data, OPC-completed layout data or the like.

Meanwhile, a taxicab or Manhattan OPC method is proposed as an OPC method, which divides a polygonal layout pattern into a plurality of edges and moves the plurality of edges so that an adjusted or corrected pattern has a Manhattan path. In some cases, in order to provide improved quality mask data, a curvilinear OPC method has been proposed, which adjusts or corrects a layout pattern into a curved shape using an inverse lithography technology (ILT).

The curvilinear OPC may have several advantages over the Manhattan OPC. For example, when layout patterns are corrected to have a curved shape, it may be easier to dispose corrected patterns to satisfy a mask rule (MR) in a mask layout space, compared to when they are corrected to have a polygonal shape. Alternatively or additionally, when patterns are corrected to have a curved shape in manufacturing a mask, the corrected patterns can be more precisely implemented on the mask compared to when they are corrected to have a polygonal shape. This may be because when patterning a chrome film with an e-beam when manufacturing a mask, a curved shape can in some cases be more precisely implemented with an e-beam than a polygonal shape. Additionally or alternatively, as compared to polygonal patterns, curved patterns can more accurately implement a desired size and shape of a photoresist pattern to be actually developed.

However, compared to performing the Manhattan OPC, a turnaround time (TAT) may increase when the curvilinear OPC is performed, and a data capacity of completed layout patterns may increase. This may be because, unlike moving a layout pattern on an edge-by-edge basis when performing the Manhattan OPC, the layout pattern is adjusted on a pixel-by-pixel basis when performing the curvilinear OPC.

According to various example embodiments, in one target pattern included in a layout, the curvilinear OPC may be applied to a corner section, while the Manhattan OPC may be applied to an edge section. By applying the curvilinear OPC to the corner section, the corner section may be flexibly corrected, making it easier for a corrected pattern to satisfy the mask rule. By applying the Manhattan OPC to the edge section, an overall TAT of the OPC may be reduced, and/or a data capacity for the corrected pattern may be reduced.

For example, a curved target pattern may be created by rounding off the corners of a polygonal target pattern included in the layout, and the curved target pattern may be divided into (or partitioned into) a linear section pattern and a curved section pattern. The linear section pattern may be modified into a linear shape by applying the Manhattan OPC to the linear section pattern, and the curved section pattern may be modified into a curved shape by applying the curvilinear OPC to the curved section pattern. Then, a corrected pattern may be created by merging the modified linear section pattern and the modified curved section pattern.

Hereinafter, before the OPC method according to various example embodiments is explained in detail, a method of manufacturing a semiconductor chip using the OPC method is described.

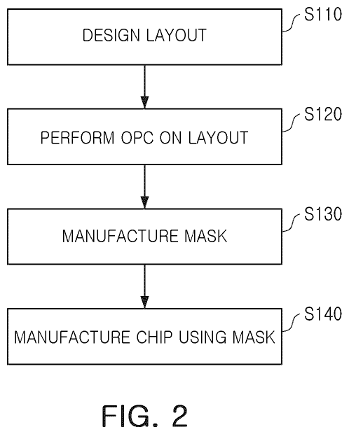

FIG. 2 is a flowchart illustrating a method of manufacturing a semiconductor chip according to various example embodiments.

Referring to FIG. 2, the semiconductor chip manufacturing method may include operations S110 to S140.

In operation S110, a design layout of a semiconductor chip may be designed. The design layout corresponding to a circuit pattern of the semiconductor chip or device to be formed on a substrate may be provided from a host computer and/or server of the semiconductor manufacturing facility and/or from a client of a foundry semiconductor manufacturing facility. Specifically, the layout is (or includes) a physical indication for a circuit designed for the semiconductor chip to be transferred onto or patterned and formed on and in the substrate, and may include a plurality of patterns. For example, the design layout may be provided as coordinate values of a contour of patterns included in the design layout from a computer aided design (CAD) system. In some examples, the patterns may include multiple patterns in which the same shape is iterated, and the patterns may be provided in a shape of a combination of polygons such as a triangle or a quadrangle.

In operation S120, each of an OPC operation and a position correction operation for the design layout may be performed. As described above, OPC refers to an adjustment or a correction that changes patterns included in a design layout by reflecting errors due to an optical proximity effect. As patterns are increasingly refined, an optical proximity phenomenon may occur due to an influence (or diffraction) between neighboring patterns during a photolithography process.

Therefore, by performing OPC for correcting the design layout, an occurrence of the optical proximity effect may be suppressed or reduced by performing optical proximity correction to correct the design layout. By the OPC, a distortion phenomenon of a pattern due to diffraction and interference of light generated during the photolithography process may be corrected or at least partially corrected or improved upon, and an error caused by a pattern density may be corrected or at least partially corrected or improved upon. After the OPC operation, an OPC correction verification operation may be further performed.

For example, when mask data is input to an OPC model, a contour of the circuit pattern to be transferred to the substrate and/or to films on the substrate may be predicted through a simulation. The OPC verification may be performed based on a difference between the contour and a target pattern actually desired to be formed on the substrate. The OPC model is (or includes) a simulation model for predicting the contour of the transferred circuit pattern, and various basic data may be input into the OPC model as an input data. For example, the basic data may include data of target patterns, as well as information data such as thickness, refractive index and dielectric constant for photoresist (PR) data, and data of a source map for a shape of an illumination system. However, the basic data is not limited to the data illustrated above.

The position correction may include moving a position of an optical-proximity-corrected pattern in consideration of physical deformation and change of a lower structure in which the patterns are to be aligned. Deformation of the lower structure may occur due to factors during the manufacturing process of the semiconductor chip. Due to the deformation of the lower structure, progressive misalignment in which the actual pattern positions of the patterns of the lower structure are changed from the original layout may be caused. The position correction may be moving only the position, without changing a shape of the optical-proximity-corrected pattern.

A final layout data corrected by the OPC and the position correction in operation S120 may be transmitted to a photolithography equipment for manufacturing a mask to be used in the lithography process, such as a photomask and an electron beam mask.

In operation S130, a mask may be manufactured according to the corrected design layout data. A mask can be manufactured by performing the lithography process on the mask substrate or mask blank, by using the corrected or adjusted layout data. After the lithography process, a series of processes, such as one or more of developing, etching, cleaning, and baking further performed on the mask substrate for forming the mask. Depending on example embodiments, before transmitting the corrected design layout data, a verification operation for the corrected design layout data may be further performed.

In operation S140, a semiconductor chip may be manufactured using a mask. For example, a semiconductor chip may be manufactured by performing the photolithography process on a substrate and/or on films that are on the substrate using the manufactured mask. The semiconductor chip may include a volatile memory such as one or more of a dynamic random access memory (DRAM), a static random access memory (SRAM), or the like, and/or a nonvolatile memory such as a flash memory. Alternatively or additionally, the semiconductor chip may include a logic semiconductor device, such as a micro-processor, for example, one or more of a central processing unit (CPU), a controller, or an application specific integrated circuit (ASIC). The semiconductor chip may be finally manufactured by further performing one or more of a deposition process, an etching process, an ion (implantation) process, a cleaning process, a polishing process, etc. in addition to the photolithography process.

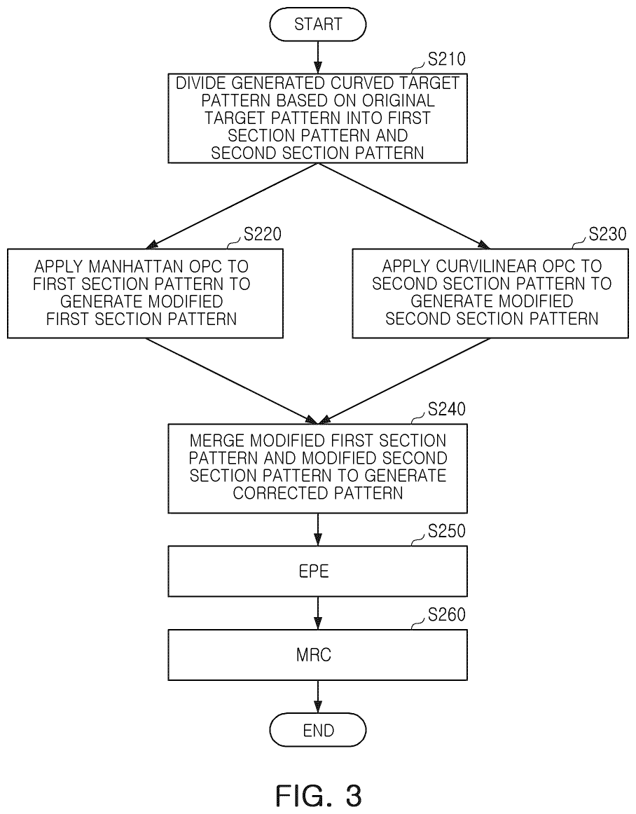

Hereinafter, an OPC method according to various example embodiments will be described in detail with reference to FIGS. 3 to 12.

FIG. 3 is a flowchart illustrating an OPC method according to various example embodiments.

Referring to FIG. 3, the OPC method according to various example embodiments may correspond to operation S120 described with reference to FIG. 2 and may include operations S210 to S260. Operations S210 to S260 may be performed by the processor 1100 executing the OPC tool 1220 in the computing system 1000 described with reference to FIG. 1.

Prior to, concurrently with, serially with, or after executing operation S210, original target patterns included in the design layout may be obtained from a database. Hereinafter, a method of performing OPC on an original target pattern will be described using one original target pattern as an example.

In operation S210, the curved target pattern generated based on the original target pattern may be divided into (or partitioned into) a first section pattern and a second section pattern. For example, the original target pattern may be a polygonal pattern, and a curved target pattern may be formed by rounding off corners of the original target pattern. A shape identical to that or nearly identical to that of the curved target pattern may be aimed to be formed on the substrate.

In the curved target pattern, a linear portion may be determined as the first section pattern, and a curved portion may be determined as the second section pattern. The first section pattern may correspond to an edge portion of the original target pattern, and the second section pattern may correspond to a corner portion of the original target pattern.

In operation S220, a modified first section pattern may be generated by applying Manhattan OPC to the first section pattern. For example, by moving the edges of the first section pattern, the first section pattern may be modified to have a linear shape.

In operation S230, a modified second section pattern may be generated by applying curvilinear OPC to the second section pattern. For example, the second section pattern may be modified to have a curved shape by being modified according to a curve function based on a control point.

In some example embodiments, operations S220 and S230 may be performed simultaneously and in parallel. However, example embodiments are not limited thereto, and operation S230 may be performed after at least partially after operation S220, and/or operation S220 may be performed after or at least partially after operation S230. Furthermore in some examples, operations S220 and S230 may be performed iteratively.

In operation S240, an adjusted or corrected pattern may be generated by merging the modified first section pattern and the modified second section pattern. For example, the corrected pattern may include linear edges and curved corners.

In operation S250, an edge placement error (EPE) may be calculated based on the corrected pattern. For example, by performing a simulation based on the corrected pattern, a contour of the pattern to actually be formed on the substrate when the mask has the corrected pattern may be predicted, and an error between the predicted contour and the curved target pattern may be calculated.

In some example embodiments, when the EPE calculation result shows that the EPE of the predicted pattern and the curved target pattern exceeds a critical level, operations S220 to S240 may be repeatedly performed until the EPE reaches the critical level within a number of repetitions such as a dynamically determined (or, alternatively, predetermined) number of repetitions, whereby the shape of the corrected pattern can be adjusted.

In operation S260, a mask rule check (MRC) may be performed based on the corrected pattern. For example, it may be verified as to whether the corrected pattern itself has no defects such as jogs, and/or it may be verified as to whether a distance between the corrected pattern and a pattern adjacent to the corrected pattern is greater than or equal to a critical distance.

Once operations S210 to S260 are completed for each of the original target patterns obtained from the design layout, a corrected layout data including the corrected patterns generated from the original target patterns may be stored in the database.

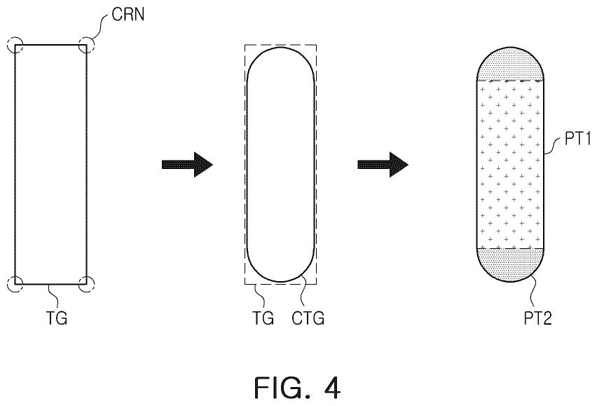

Next, the method of performing operation S210 will be described in more detail with reference to FIGS. 4 to 6.

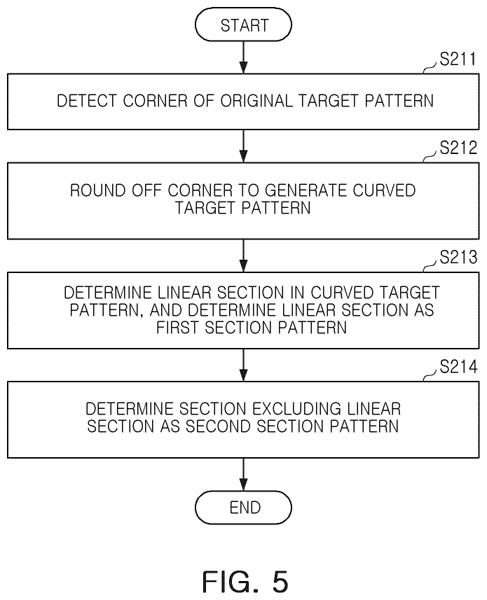

FIGS. 4 and 5 are diagrams illustrating a method of dividing sections of a target pattern according to various example embodiments.

Referring to FIGS. 4 and 5 together, in operation S211, corners of an original target pattern TG may be detected. The original target pattern TG may be obtained from the design layout, and may have a polygonal shape. The corners CRN may be detected from the original target pattern TG.

For example, the shape may be a convex or concave or convex-concave shape, and in some cases may be a rectangle or a bent rectangle or a polyomino shape, etc. As described with reference to FIG. 4, the shape is illustrated as a rectangle; however, example embodiments are not limited thereto.

In operation S212, a curved target pattern CTG may be created by rounding around the corners CRN of the original target pattern TG. For example, among the points constituting (or included in) the original target pattern TG, the surroundings of the corners (CRN) may be rounded off or beveled by modifying the positions of the points included in the area within a specified range from the corners CRN along a gentle curve.

According to various example embodiments, the OPC may be performed based on a curve target pattern CTG. For example, the OPC may be performed by modifying the curve target pattern CTG, and the OPC may be performed so that the pattern actually formed on the substrate is closer to the curve target pattern CTG.

In operation S213, a linear section may be determined in the curve target pattern CTG, and the linear section may be determined as a first section pattern PT1 for applying the Manhattan OPC. Before, concurrently, or afterwards, in operation S214, a curved section excluding the linear section may be determined in the curve target pattern CTG, and the curved section may be determined as a second section pattern PT2 for applying the curvilinear OPC. The first section pattern PT1 may correspond to an edge section in the original target pattern TG, and the second section pattern PT2 may correspond to a corner section of the original target pattern TG.

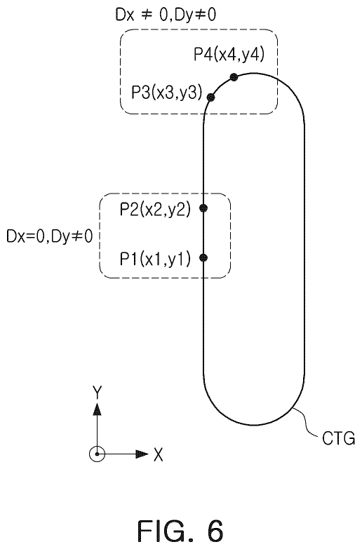

FIG. 6 is a diagram illustrating a method of detecting a linear section in a curved target pattern according to various example embodiments.

FIG. 6 illustrates the curved target pattern CTG described with reference to FIG. 4. The curved target pattern CTG may be defined as a number of points on coordinates having a first axis X and a second axis Y intersecting the first axis X. FIG. 6 illustrates any four points (P1-P4) among the number of points.

According to various example embodiments, a set of points in the curved target pattern (CTG), which are consecutive to each other and whose first X-axis positions or second Y-axis positions intersecting the first axis positions are the same, may be determined as a linear section pattern. Additionally, a set of points, which are consecutive to each other and who do not have a common first X-axis positions or second Y-axis positions intersecting the first axis positions, may be determined as a curved section pattern.

For example, at the first point P1 with coordinates (x1, y1) and the second point P2 with coordinates (x2, y2), Dx and Dy may be defined as follows: Dx=(x1−x2)=0; and Dy=(y1−y2)≠0. The first point P1 and the second point P2 may be points where the X-axis positions do not change. A set of points, which are consecutive with each other and have no change in the X-axis positions, including the first point P1 and the second point P2, may be determined as the linear section pattern. Likewise, if there are points which are consecutive with each other and have no changes in the Y-axis positions, the set of points may also be determined as the linear section pattern.

Furthermore, at the third point P3 with coordinates (x3, y3) and the fourth point P4 with coordinates (x4, y4), Dx and Dy may be defined as follows: Dx=(x3−x4)≠0; and Dy=(y3−y4)≠0. The third point P3 and the fourth point P4 may be points where the X-axis positions and Y-axis positions change. A set of points, which are consecutive with each other and have changes in the X-axis positions and Y-axis positions, including the third point P3 and the fourth point P4, may be determined as the curved section pattern.

Meanwhile, the method of dividing or partitioning the curved target pattern CTG into a linear section pattern and a curved target pattern is not limited to the method described with reference to FIG. 6. For example, in the curved target pattern CTG, points included in a region within a range determined based on the corner of the original target pattern TG may be determined as the curved target pattern, and remaining points may be determined as the linear target pattern.

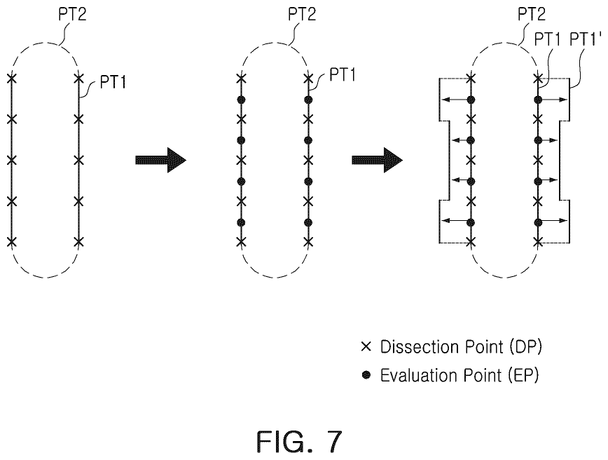

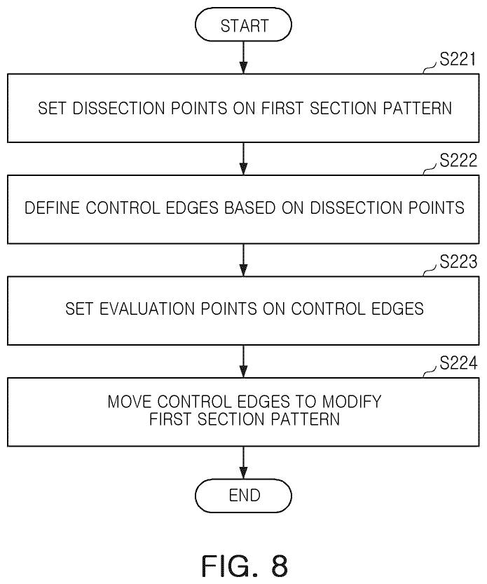

Next, the method of performing operation S220 described with reference to FIG. 2 will be described in more detail with reference to FIGS. 7 and 8.

FIGS. 7 and 8 are diagrams illustrating a method of performing Manhattan OPC on a first section pattern according to various example embodiments.

Referring to FIGS. 7 and 8, dissection points DP may be determined on the first section pattern PT1 in operation S221. The dissection point DP may refer to a point for dissecting or partitioning the first section pattern PT1 into a plurality of edges to perform Manhattan OPC.

In FIG. 7, the first section pattern PT1 is illustrated as a solid line, and the second section pattern PT2 is illustrated as a dashed line. In addition, a plurality of dissection points DP are illustrated on the first section pattern PT1.

In some example embodiments, a plurality of dissection points DP may be set at an interval, such as a dynamically determined (or, alternatively, a predetermined) interval on the first section pattern PT1. For example, a dissection points PT may be set at the boundary between the first section pattern PT1 and the second section pattern PT2, and the dissection points DP may be set according to the length of the first section pattern PT1. A number, such as a dynamically determined (or, alternatively, a predetermined) number of dissection points DP may be additionally set at a dynamically determined (or, alternatively, a predetermined) interval, or if an interval between the dissection points DP is less than a standard value, additional dissection points may not be set.

In operation S222, control edges may be defined based on the dissection points DP. The control edge may refer to a unit that can move independently to modify the first section pattern PT1. Two adjacent dissection points DP may define a control edge.

In operation S223, evaluation points EP may be set on the control edges. The evaluation point EP may refer to a reference point for calculating the EPE of the corrected pattern. In some example embodiments, the evaluation points EP may be set at a midpoint of each of the control edges, that is, at a midpoint of the two adjacent dissection points DP. However, example embodiments are not limited thereto, and the evaluation points EP may be formed at arbitrary positions on the control edges.

In operation S224, the first section pattern PT1 may be modified by moving the control edges. Each control edge may move in a direction perpendicular to (or orthogonal to) the direction in which the control edge extends, and may move by a distance determined to compensate for or improve over the optical proximity effect. FIG. 7 illustrates the first section pattern PT1, the movement amount and direction of each control edge, and the modified first section pattern PT1′.

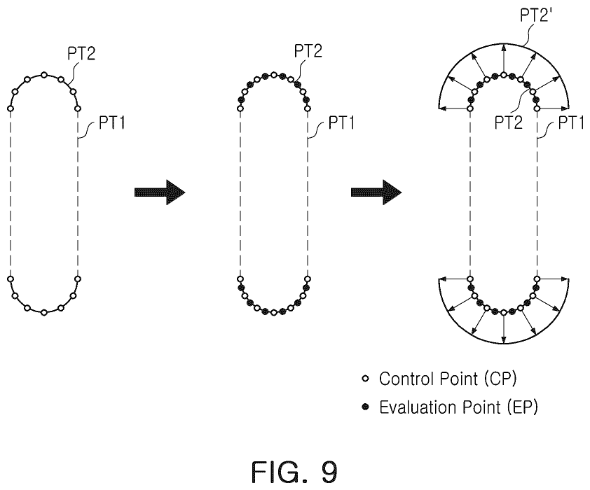

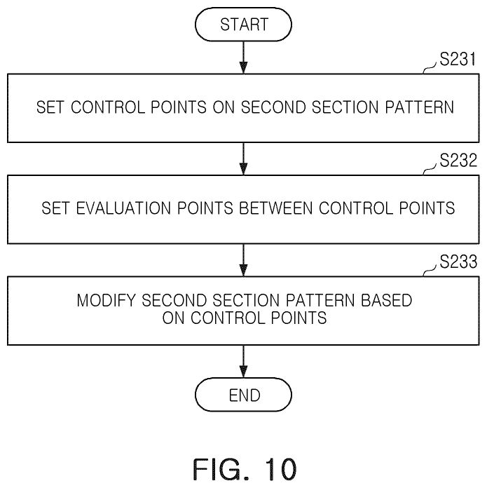

Next, the method of performing operation S230 described with reference to FIG. 2 will be described in more detail with reference to FIGS. 9 and 10.

FIGS. 9 and 10 are diagrams illustrating a method of performing the curvilinear OPC on a second section pattern according to various example embodiments.

Referring to FIGS. 9 and 10, control points CP may be set on the second section pattern PT2 in operation S231. The control point CP may refer to a reference point for modifying the second section pattern PT2 to perform the curvilinear OPC.

In FIG. 9, the second section pattern PT2 is illustrated as a solid line, and the first section pattern PT1 is illustrated as a dashed line. In addition, a plurality of control points CP are illustrated on the second section pattern PT2.

In some example embodiments, a plurality of control points CP may be set at intervals, such as dynamically determined (or, alternatively, predetermined) intervals on the second section pattern PT2. For example, the control points CP may set at the boundary between the second section pattern PT2 and the first section pattern PT1, and the control points CP may be set according to a length of the second section pattern PT2. The control points CP at equal interval may be additionally set, or if the distance between the control points CP is less than a standard value, additional control points may not be set.

In operation S232, evaluation points EP may be set on the second section pattern PT2 based on the control points CP. In some example embodiments, the evaluation points EP may be set at positions having the same distance from the two adjacent control points CP on the second section pattern PT2. However, example embodiments are not limited thereto, and the evaluation points EP may be formed at any position on the second section pattern PT2.

In operation S233, the second section pattern PT2 may be modified based on the control points CP. For example, each control point CP may move in a direction perpendicular to a tangent line between the control point CP and the second section pattern PT2, and may move by a distance determined to compensate for an optical proximity effect. In some cases, the control points may define a new second section pattern PT2′, which is conformal with the second section pattern PT2′; example embodiments are not limited thereto. In some examples, the second section pattern PT2 may be modified into a curve that passes through all of the moved control points CP using a curve function. FIG. 9 illustrates the second section pattern PT2, the movement amount and direction of each of the control points CP, and the modified second section pattern PT2.

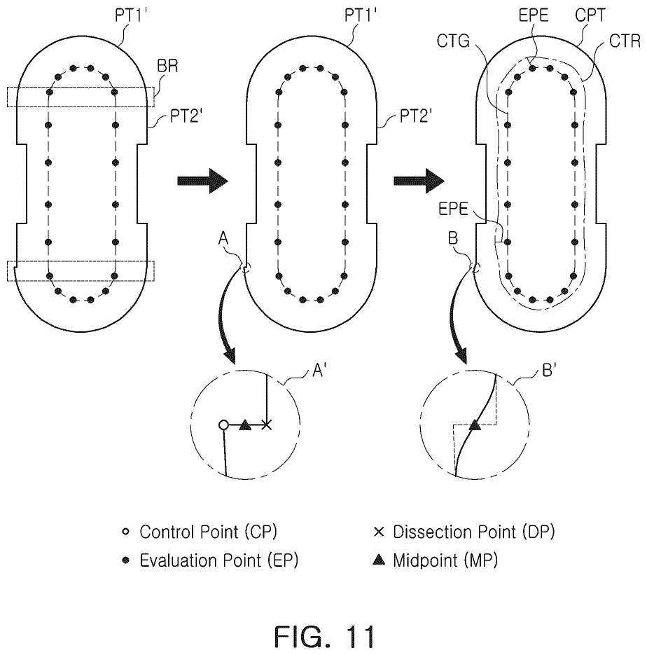

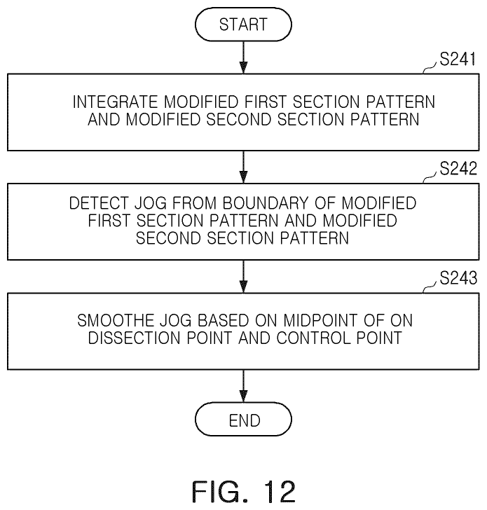

Next, the method of performing operation S240 described with reference to FIG. 2 will be described in detail with reference to FIGS. 11 and 12.

FIGS. 11 and 12 are diagrams illustrating a method of merging a modified first section pattern and a modified second section pattern according to various example embodiments.

Referring to FIGS. 11 and 12, in operation S241, the modified first section pattern PT1′ and the modified second section pattern PT2′ may be integrated into one pattern. In some example embodiments, the modified second section pattern PT2′ may be added to the modified first section pattern PT1′.

Since different types of OPCs are applied to the first section pattern PT1 and the second section pattern PT2, respectively, when the modified patterns are simply added, the boundaries of the modified patterns may not match, and the boundaries may be misaligned, thereby causing a jog. In some cases, this jog may be difficult to pattern with a photolithographic process.

In operation S242, a jog may be detected from the boundary between the modified first section pattern PT1′ and the modified second section pattern PT2′. In some example embodiments, a boundary region BR of the modified first section pattern PT1′ and the modified second section pattern PT2′ may be set, and the MRC may be performed in the boundary region BR so as to determine a presence or absence of a jog.

In FIG. 11, a region A containing a jog and an enlarged view A′ of the region A are illustrated. Referring to the enlarged view A′, a location of the control edge including the dissection point DP at the boundary of the first section pattern and a location of the control point CP at the boundary of the second section pattern may be misaligned, resulting in the region A containing a jog.

In operation S243, the jog may be smoothed based on a midpoint MP of the dissection point EP and the control point CP constituting the jog, whereby merging the modified first section pattern PT1′ and the modified second section pattern PT2′ may be completed. For example, using a smoothing function such as but not limited to a spline-fitting function, the jog may be modified into a curve that passes through the midpoint MP and smoothly connect the modified first section pattern PT1′ and the modified second section pattern PT2′.

In FIG. 11, a merged corrected pattern CPT is illustrated. In the corrected pattern CPT, a region B containing a smoothed jog and an enlarged view B′ of the region B are illustrated.

Meanwhile, FIG. 11 illustrates the curved target pattern CTG described with reference to FIG. 4, and the evaluation points EP set on the curved target pattern CTG and described with reference to FIGS. 7 and 9. The evaluation points EP may include the evaluation points set on the first section pattern PT1 while performing the Manhattan OPC, and the evaluation points set on the second section pattern PT2 while performing the curvilinear OPC.

In some example embodiments, a contour CTR of a pattern that can be formed on a substrate may be predicted based on the corrected pattern CPT, and an error between the contour CTR and the curved target pattern CTG may be calculated as the EPE described in operation S250 of FIG. 3 based the evaluation points EP. For example, based on the evaluation point EP, a distance from the contour CTR in a direction perpendicular to the corrected pattern CPT may be calculated as the EPE.

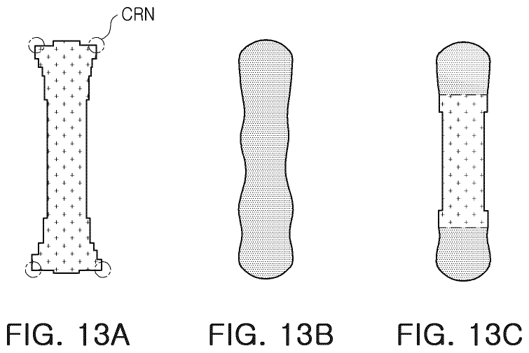

Next, an effect of OPC according to various example embodiments will be described with reference to FIGS. 13A to 13C.

FIGS. 13A to 13C are diagrams comparing and illustrating the Manhattan OPC, the curvilinear OPC, and the OPC according to various example embodiments.

FIGS. 13A to 13C illustrate the corrected patterns generated by applying different OPC methods to the same original target pattern. FIG. 13A illustrates a corrected pattern generated by Manhattan OPC, FIG. 13B illustrate a corrected pattern generated by curvilinear OPC, and FIG. 13C illustrate a corrected pattern generated by OPC according to various example embodiments.

Comparing the corrected patterns of FIGS. 13A and 13B, the corrected pattern of FIG. 13A may have a relatively protruding corner region CRN, while the corrected pattern of FIG. 13B may have a relatively smoothing corner region CRN without a protruding corner portion. Therefore, the corrected pattern in FIG. 13B may be relatively easy to comply with the mask rule in relationship with adjacent corrected patterns, while the corrected pattern in FIG. 13A may be difficult to comply with the mask rule in relationship with adjacent corrected patterns.

Meanwhile, the corrected pattern in FIG. 13A may be generated by moving edges included in the original target pattern, and may have a relatively simple form to be processed on a computer. In contrast, the corrected pattern in FIG. 13B may be generated by modifying the curved target pattern generated from the original target pattern on a pixel-by-pixel basis, and may have a relatively complex form to be processed on a computer. In some example embodiments, the TAT of the curvilinear OPC may be longer than that of the Manhattan OPC, and the data capacity representing the corrected pattern in FIG. 13B may be greater than the data capacity representing the corrected pattern in FIG. 13A.

According to various example embodiments, the corrected pattern of FIG. 13C may have a mixed form of the corrected pattern of FIG. 13A and the corrected pattern of FIG. 13B. Specifically, the corrected pattern in FIG. 13C may have a non-protruding form in the corner portion by applying the curvilinear OPC thereto, and may have a simple form the edge portion for processing on a computer by applying the Manhattan OPC thereto. Since the corners of the corrected pattern in FIG. 13C are processed similarly to the corrected pattern in FIG. 13B, it may be easy to comply with the mask rule like the corrected pattern in FIG. 13B.

Furthermore, the data capacity of the corrected pattern in FIG. 13C) may be reduced close to the data capacity of the corrected pattern in FIG. 13A. For example, the corrected pattern in FIG. 13A may have 58 vertices, the corrected pattern in FIG. 13B may have 186 vertices, and the corrected pattern in FIG. 13C may have 77 vertices. Therefore, the data capacity of the corrected pattern in FIG. 13C may be approximately 25% greater than the data capacity of the corrected pattern in FIG. 13A, and may be at least 50% less than the data capacity of the corrected pattern in FIG. 13B.

Next, a method of manufacturing a mask using a corrected layout based on the OPC method according to various example embodiments will be described.

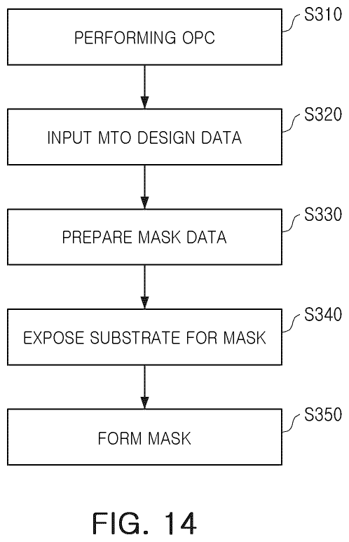

FIG. 14 is a flow chart illustrating a mask manufacturing method according to various example embodiments.

Referring to FIG. 14, the mask manufacturing method may include operations S310 to S350.

In operation S310, the OPC according to various example embodiments may be performed.

According to various example embodiments, a curved target pattern may be generated by rounding off the corners of a polygonal target pattern included in the layout, and the curved target pattern may be divided into a linear section pattern and a curved section pattern. The linear section pattern may be modified into a linear shape by applying the Manhattan OPC to the linear section pattern, and the curved section pattern may be modified into a curved shape by applying the curvilinear OPC to the curved section pattern. Then, a corrected pattern may be generated by merging the modified linear section pattern and the modified curved section pattern.

After performing the OPC, in operation 320, mask tape-out (MTO) data may be obtained. In general, the MTO may include requesting to manufacture a mask by handing over mask design data on which the OPC operation has been completed. Accordingly, the MTO design data may be considered as mask design data on which the OPC operation has been completed. Such an MTO design data may have a graphic data format used in electronic design automation (EDA) software or the like. For example, the MTO design data may have a data format such as one or more of graphic data system (GDS2 or GDSII), open artwork system interchange standard (ASIS), or the like.

After obtaining the MTO design data, in operation S330, mask data preparation (MDP) may be performed. The mask data preparation may include, for example, one or more of format conversion known as fracturing, augmentation of barcodes for mechanical reading, standard mask patterns for inspection, job decks, etc., and verification in automatic and manual methods, where the job-deck may include creating a text file related to a series of instructions, such as arrangement information of multiple mask files, a reference dose, and a photolithography speed or method.

Meanwhile, format conversion, that is, fracturing may include a process of dividing the MTO design data for each region and changing the divided MTO design data to a format for an electron beam photolithography machine. For example, the fracturing may include one or more of data manipulation such as scaling, data sizing, data rotation, pattern reflection, and color inversion. In the conversion process through fracturing, data for numerous systematic errors that may occur during a transfer process from design data to an image on a substrate may be corrected. A data correction process for these systematic errors may refer to mask process correction (MPC). For example, the data correction process may include adjusting a line width and increasing precision of pattern arrangement, called CD adjustment. In some cases, the data correction process may be or may include a process performed in advance for the mask process correction. Here, systematic errors may be caused by distortion occurring in a photolithography process, a mask development, an etching process, and a substrate imaging process.

Meanwhile, the mask data preparation may include the aforementioned MPC. The MPC refers to a process of correcting an error occurring during a photolithography process, for example, a systematic error. Here, the photolithography process may be a concept in which the MPC process generally includes electron beam writing, developing, etching, and baking. In some cases, data processing may be performed prior to the photolithography process. The data processing is or includes a kind of preprocessing process for mask data, and may include grammar check for mask data, prediction of exposure time, and the like.

After preparing the mask data, in operation S340, the substrate for a mask (or the mask blank) is exposed based on the mask data. Here, the exposure may include, for example, electron beam writing. Here, the electron beam writing may be performed by, for example, a gray writing method using a multi-beam mask writer (MBMW). In addition, the electron beam writing may be performed using a variable shape beam (VSB) photolithography machine.

Meanwhile, after the mask data preparation operation, a process of converting the mask data into pixel data may be performed before the photolithography process. The pixel data is data directly used for actual photolithography, and may include data regarding a shape to be exposed and data regarding a dose assigned thereto each data. Here, the data regarding the shape may be bit-map data in which shape data, which is vector data, is converted through rasterization or the like.

As described with reference to FIGS. 13A to 13C, a number of vertices of the corrected pattern generated by the OPC according to various example embodiments may be close to a number of vertices of the corrected pattern generated by Manhattan OPC, while a shape of the corrected pattern generated by the OPC according to various example embodiments may be similar to the shape of the corrected pattern generated by the curvilinear OPC. In some cases, even if a smaller amount of data regarding the shape to be exposed by the mask is used, a mask capable of exposing a pattern with high similarity to the curved target pattern may be formed on the substrate. That is, while reducing the TAT of the mask photolithography process, the quality of the generated mask may be improved.

After the photolithography process, in operation S450, a mask may be formed by performing a series of processes. The series of processes may include, for example, development, etching, and cleaning. In addition, the series of processes for forming the mask may include a measurement process, a defect inspection process or a defect repair process. In some examples, a pellicle application process may also be included, where the pellicle application process may include a process of attaching a pellicle to a mask surface to protect the mask from subsequent contamination during a delivery of the mask and a useful life of the mask when it is confirmed that there are no contaminating particles or chemical stains through final cleaning and inspection.

The optical proximity correction method, the mask manufacturing method using the same, and the semiconductor chip manufacturing method according to various example embodiments may more easily satisfy the mask rule by applying a mixture of the curvilinear correction and the Manhattan correction to one layout pattern, while also reducing a data capacity including the layout pattern.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While some example embodiments have been shown and described above, it will be apparent to those of ordinary skill in the art that modifications and variations could be made without departing from the scope of inventive concepts as defined by the appended claims. Furthermore, example embodiments are not necessarily mutually exclusive with one another. For example, some example embodiments may include one or more features described with reference to one or more figures, and may also include one or more other features described with reference to one or more other figures.

What is claimed is:

1. An optical proximity correction (OPC) method for manufacturing a semiconductor chip, comprising:
detecting corners of an original target pattern having a polygonal shape;
rounding off the corners to generate a curved target pattern;
dividing the curved target pattern into a linear section pattern and a curved section pattern;
applying Manhattan OPC to the linear section pattern to generate a modified linear section pattern;
applying curvilinear OPC to the curved section pattern to generate a modified curved section pattern; and
merging the modified linear section pattern and the modified curved section pattern to generate a corrected pattern.

2. The OPC method of claim 1, wherein the rounding off the corners to generate the curved target pattern comprises:
modifying positions of points included in a region within a range from the detected corners, the points being modified selected from among points included in the original target pattern along a curve.

3. The OPC method of claim 1, wherein the dividing the curved target pattern into the linear section pattern and the curved section pattern comprises:
determining a set of points in the curved target pattern as the linear section pattern, the set of points consecutive to each other and having positions in a first axis or positions in a second axis intersecting the first axis be the same.

4. The OPC method of claim 3, wherein the dividing the curved target pattern into the linear section pattern and the curved section pattern comprises:
determining a set of points in the curved target pattern as the curved section pattern, the set of points consecutive to each other and whose positions in a first axis and positions in a second axis intersecting the first axis be different.

5. The OPC method of claim 1, wherein the dividing the curved target pattern into the linear section pattern and the curved section pattern comprises:
determining points included in a region within a range determined based on the corners of the original target pattern as a curved target pattern;
and determining remaining points included in the region as a linear target pattern.

6. The OPC method of claim 1, wherein the applying Manhattan OPC to the linear section pattern to generate the modified linear section pattern comprises:
setting a plurality of dissection points on the linear section pattern;
defining a plurality of control edges based on the plurality of dissection points;
setting a plurality of evaluation points on the plurality of control edges; and
modifying the linear section pattern by moving at least one of the plurality of control edges.

7. The OPC method of claim 6, wherein the setting the plurality of dissection points on the linear section pattern comprises:
setting dissection points at a boundary of the linear section pattern; and
further setting a number of dissection points at an interval from along a length of the linear section pattern between the dissection points set at the boundary.

8. The OPC method of claim 6, wherein the setting the plurality of evaluation points on the plurality of control edges comprises:
setting each evaluation point at a midpoint of each of the plurality of control edges.

9. The OPC method of claim 1, wherein the applying curvilinear OPC to the curved section pattern to generate the modified curved section pattern comprises:
setting a plurality of control points on the curved section pattern;
setting a plurality of evaluation points on the curved section pattern based on the plurality of control points;
moving each of the plurality of control points; and
modifying the curve section pattern into a curve passing through the plurality of control points.

10. The OPC method of claim 9, wherein the setting the plurality of control points on the curved section pattern comprises:
setting dissection points at a boundary of the curved section pattern; and
further setting a number of dissection points at an interval along a length of the curved section pattern between the dissection points set at the boundary.

11. The OPC method of claim 9, wherein the setting the plurality of evaluation points on the curved section pattern based on the plurality of control points comprises:
setting the plurality of evaluation points at positions having a same distance from two adjacent control points on the curved section pattern.

12. The OPC method of claim 1, wherein the merging the modified linear section pattern and the modified curved section pattern to generate the corrected pattern comprises:
adding up the modified linear section pattern and the modified curved section pattern;
detecting a jog at a boundary between the modified linear section pattern and the modified curved section pattern; and
smoothing the jog based on a midpoint of a dissection point of the modified linear section pattern and a control point of the modified curved section pattern constituting the jog.

13. The OPC method of claim 12, wherein the detecting the jog at a boundary between the modified linear section pattern and the modified curved section pattern comprises:
detecting a presence and a location of the jog by performing a mask rule check (MRC) at the boundary.

14. The OPC method of claim 1, further comprising
performing an OPC simulation based on the corrected pattern;
calculating an edge placement error (EPE) of the corrected pattern using a contour generated according to the OPC simulation;
performing a mask rule check (MRC) of the corrected pattern;
determining a final corrected pattern according to a calculation result of the EPE and a calculation result of the MRC.

15. The OPC method of claim 14, wherein the calculating the EPE of the corrected pattern using the contour generated according to the OPC simulation comprises:
calculating an error between the contour and the curved target pattern based on each of first evaluation points formed in the linear section pattern and second evaluation points formed in the curved section pattern.

16. The OPC method of claim 1, further comprising:
obtaining the original target pattern from a design layout stored in a database; and
saving a corrected layout including the corrected pattern in the database.

17. A semiconductor chip manufacturing method, comprising:
designing a layout for a semiconductor chip;
performing optical proximity correction (OPC) on the layout;
manufacturing a mask corresponding to the layout after performing OPC; and
manufacturing the semiconductor chip using the mask,
wherein the mask comprises a layout pattern, and
the layout pattern comprises a polygonal section and a curved section.

18. The semiconductor chip manufacturing method of claim 17, wherein the polygonal section includes an edge section of the layout pattern, and the curved section includes a corner section of the layout pattern.

19. The semiconductor chip manufacturing method of claim 18, wherein
the polygonal section comprises a set of points among a plurality of points included the layout pattern, the set of consecutive to each other and having positions in a first axis or positions in a second axis intersecting the first axis be the same, and
the curved section comprises a set of points among a plurality of points constituting the layout pattern, the set of points consecutive to each other and having positions in the first axis and positions in the second axis be different.

20. A mask manufacturing method for a semiconductor chip, the method comprising:
performing optical proximity correction (OPC) on a layout;
receiving mask tape-out (MTO) design data after performing OPC;
performing mask data preparation after receiving the MTO design data;
performing a photolithography process on a substrate of a mask, based on the mask data using an electronic beam after performing the mask data preparation; and
forming a mask by performing at least one of developing, etching or cleaning process on the substrate after the photolithography process,
wherein the performing OPC comprises:
detecting corners of an original target pattern having a polygonal shape and rounding off the corners to generate a curved target pattern;
dividing the curved target pattern into a linear section pattern and a curved section pattern;
applying Manhattan OPC to the linear section pattern to generate a modified linear section pattern;
applying curvilinear OPC to the curved section pattern to generate a modified curved section pattern; and
merging the modified linear section pattern and the modified curved section pattern to generate a corrected pattern.
